(19) United States
(12) Patent Application Publication
(10) Pub. No.: US 2024/0047612 A1
(43) Pub. Date: Feb. 8, 2024

(54) LIGHT-EMITTING DEVICE AND LIGHT-EMITTING APPARATUS

(71) Applicant: XIAMEN SAN’AN OPTOELECTRONICS CO., LTD., Xiamen (CN)

(72) Inventors: Bin JIANG, Xiamen (CN); Yashu ZANG, Xiamen (CN); Gong CHEN, Xiamen (CN); Sihe CHEN, Xiamen (CN); Kang-Wei PENG, Xiamen (CN); Chung-Ying CHANG, Xiamen (CN); Weichun TSENG, Xiamen (CN); Ming-Chun TSENG, Xiamen (CN); Siyi LONG, Xiamen (CN)

(21) Appl. No.: 18/365,675

(22) Filed: Aug. 4, 2023

(30) Foreign Application Priority Data
Aug. 5, 2022 (CN) 202210937829.9

(51) Int. Cl. H01L 33/24; H01L 33/38

(52) U.S. Cl. CPC H01L 33/24; H01L 33/382; H01L 33/025

(57) ABSTRACT

A light-emitting device includes a semiconductor laminate, a first contact electrode, and a second contact electrode. The semiconductor laminate includes a first semiconductor layer, an active layer, and a second semiconductor layer being laminated in a thickness direction. The semiconductor laminate has a first portion having a patterned structure that has a first surface constituted by the first semiconductor layer, a second surface opposite to the first surface and away from the first semiconductor layer, and a side surface interconnecting the first surface and the second surface, and a second portion being a light-emitting area. The first contact electrode is formed on the first portion, electrically connected to the first semiconductor layer and in contact with the first surface, the second surface and the side surface of the patterned structure. The second contact electrode is formed on the second portion and electrically connected to the second semiconductor layer.

### CROSS-REFERENCE TO RELATED APPLICATION

This application claims priority to Chinese Invention Patent Application No. CN202210937829.9, filed on Aug. 5, 2022, which is incorporated herein by reference in its entirety.

### FIELD

The present disclosure relates to a light-emitting device (LED) and a light-emitting apparatus.

### BACKGROUND

A conventional semiconductor device that includes compounds such as gallium nitride (GaN) and aluminum gallium nitride (AIGaN), offers numerous advantages, such as a wide and adjustable energy bandgap, and may be utilized as light-emitting devices, light-receiving devices, and various types of diodes, among others.

In recent years, ultraviolet LEDs have captured the public' attention due to their immense application range and have become a new research hotspot. The ultraviolet LEDs generally include Group III nitride semiconductor materials having an aluminum (Al) component. However, the nitride semiconductor materials having Al have high electrical resistivity, and, when used in an n-type semiconductor layer, may cause a low injection efficiency of charge carriers.

### SUMMARY

Therefore, an object of the disclosure is to provide a light-emitting device and a light-emitting apparatus that can alleviate at least one of the drawbacks of the prior art.

According to one aspect of the disclosure, the light-emitting device includes a semiconductor laminate, a first contact electrode, and a second contact electrode. The semiconductor laminate includes a first semiconductor layer of a first conductivity, an active layer, and a second semiconductor layer of a second conductivity that is different from the first conductivity. The first semiconductor layer, the active layer and the second semiconductor layer are laminated in a thickness direction. The semiconductor laminate has a first portion and a second portion. The first portion has a patterned structure that has a first surface constituted by the first semiconductor layer, a second surface opposite to the first surface and away from the first semiconductor layer, and a side surface interconnecting the first surface and the second surface. The second portion is a light-emitting area. The first contact electrode is formed on the first portion, is electrically connected to the first semiconductor layer and in contact with the first surface, the second surface and the side surface of the patterned structure. The second contact electrode is formed on the second portion and electrically connected to the second semiconductor layer.

According to another aspect of the disclosure, the light-emitting apparatus includes the aforesaid light-emitting device that is an ultraviolet light-emitting diode.

### BRIEF DESCRIPTION OF THE DRAWINGS

Other features and advantages of the disclosure will become

apparent in the following detailed description of the embodiment(s) with reference to the accompanying drawings. It is noted that various features may not be drawn to scale.

FIG. 1 is a cross-section schematic view illustrating a first embodiment of a light-emitting device according to the present disclosure.

FIG. 2 is a schematic top view of the first embodiment of the light-emitting device according to the present disclosure.

FIG. 3 is a partially enlarged view of portion A of FIG. 2.

FIG. 4 is a schematic top view illustrating two portions of a semiconductor laminate included in the first embodiment of the light-emitting device according to the present disclosure.

FIG. 5 is a schematic top view illustrating a patterned structure of the semiconductor laminate of the first embodiment of the light-emitting device according to the present disclosure.

FIG. 6 is a cross-section schematic view illustrating a variation of the first embodiment of the light-emitting device according to the present disclosure.

FIG. 7 is a schematic view illustrating electrode pads of the light-emitting device shown in FIG. 5.

FIG. 8 is a cross-section schematic view illustrating a second embodiment of a light-emitting device according to the present disclosure.

FIG. 9 is a schematic top view of the second embodiment of the light-emitting device according to the present disclosure.

FIG. 10 shows partially enlarged views of patterned structures from four different types of samples.

FIG. 11 is a light output power mapping (LOP Mapping) of the four different samples.

FIG. 12 is a cross-section schematic view illustrating a third embodiment of a light-emitting device according to an exemplary embodiment of the present disclosure.

FIG. 13 is a cross-section schematic view illustrating a fourth embodiment of a light-emitting device according to an exemplary embodiment of the present disclosure.

FIG. 14 is a cross-section schematic view illustrating an embodiment of a light-emitting apparatus according to an exemplary embodiment of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

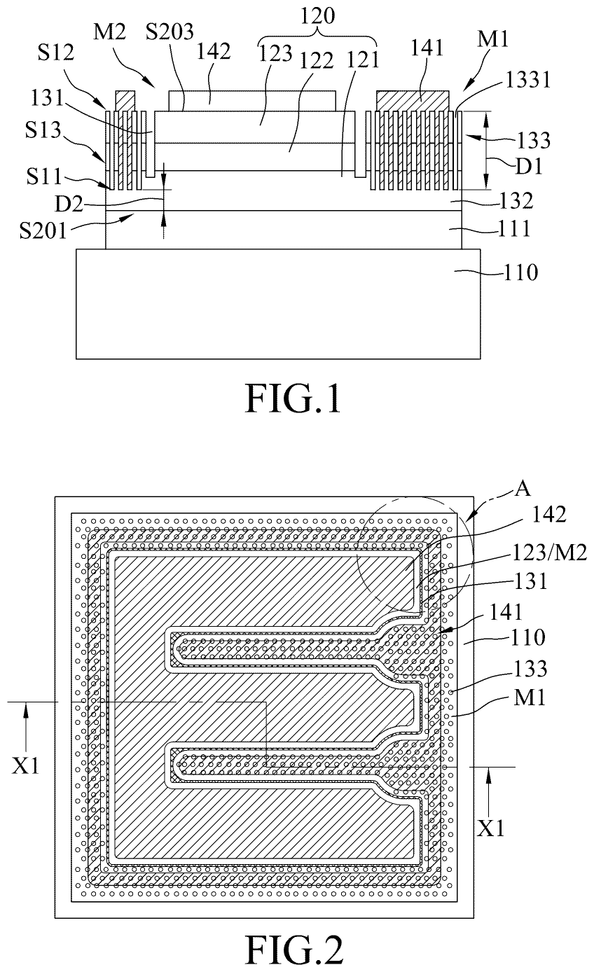

FIGS. 1 and 2 are schematic views illustrating a first embodiment of a light-emitting device of the present disclosure. FIG. 2 is a top view of the light-emitting device, and FIG. 1 is a vertical cross-sectional schematic view taken along line X1-X1 of FIG. 2. The light-emitting device as illustrated includes a substrate 110, a semiconductor laminate 120 formed on the substrate 110, a first contact electrode 141 and a second contact electrode 142.

Specifically, the substrate 110 is provided to support the semiconductor laminate 120. The substrate 110 is, for example, a sapphire substrate and may also be a growth substrate upon which a Group III nitride semiconductor may grow. In one embodiment, an aluminum nitride layer is formed on a surface of the substrate 110 to be used as an underlayer 111 that is in direct contact with the substrate 110. In some embodiments, the aluminum nitride layer, i.e. the underlayer 111, has a thickness ranging from 10 nm to 4 μm.

The semiconductor laminate 120 includes a first semiconductor layer 121, an active layer 122, and a second semiconductor layer 123 being formed and laminated in a thickness direction in such order on the aluminum nitride underlayer 111. In one embodiment, the first semiconductor layer 121 is an N-type layer and the second semiconductor layer 123 is a P-type layer, or vice versa. In one embodiment, the first semiconductor layer 121 is, for example, an n-type AlGaN layer; the active layer 122 is a layer that emits light with a specific wavelength and that has a quantum well sub-layer and a quantum barrier sub-layer; the second semiconductor layer 123 is, for example, a p-type AlGaN layer, or a p-type GaN layer, or a combination layer of both.

FIG. 3 is a partially enlarged view of portion A as shown in FIG. 2. In one specific embodiment, referring to FIGS. 1 to 3, the semiconductor laminate 120 has a first portion (M1), a second portion (M2), and an isolation structure 131 that separates the first portion (M1) and the second portion (M2). The first portion (M1) is used for a first contact electrode 141 to be formed thereon; the second portion (M2) is used as a light-emitting area. In some embodiments, the isolation structure 131 may be an isolation trench that is formed by removing the second semiconductor layer 123, the active layer 122 and a portion of the first semiconductor layer 121 between the first portion (M1) and the second portion (M2), as shown in FIGS. 1 and 3. In some embodiments, the isolation structure 131 may also be formed by increasing the resistance of the portion of the semiconductor laminate 120 between the first portion (M1) and the second portion (M2) to make the portion of the semiconductor laminate 120 electrically insulated.

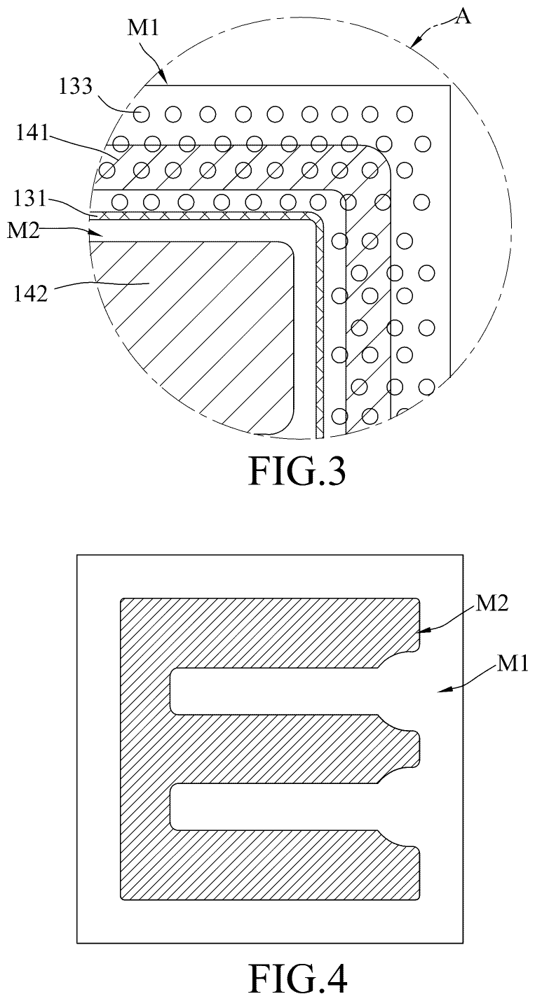

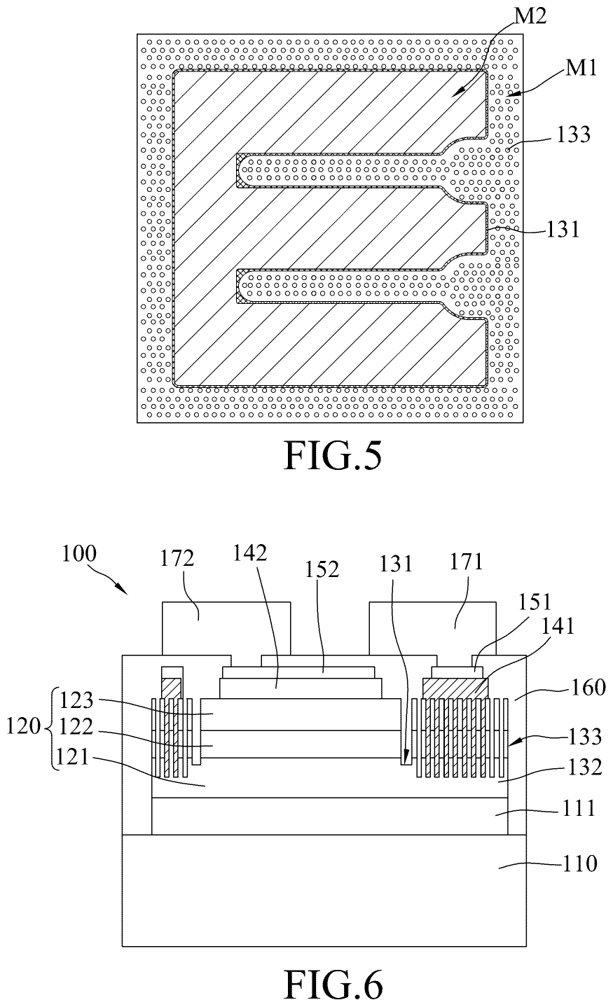

In one embodiment, the light-emitting device is an ultraviolet light-emitting device that emits ultraviolet light with a wavelength ranging from 210 nm to 380 nm, and the first semiconductor layer 121 is an n-type semiconductor layer containing Al and has poor current-spreading ability. In this embodiment, an area ratio of a projection of the first portion (M1) on an imaginary plane perpendicular to the thickness direction to a projection of the second portion (M2) on the imaginary plane may not less than 1:5 (i.e., 0.2), such as ranges from 1:5 to 1:1, and the first portion (M1) may be distributed uniformly in the semiconductor laminate 120. With such configuration, current uniformity of the light-emitting device may be increased, which is advantageous for increasing the internal quantum efficiency of the active layer and reducing the forward bias required for the light-emitting device to emit light. On the other hand, the first portion (M1), if unduly large, may lead to loss of effective area of the active layer in the light-emitting device, adversely affecting the luminous efficiency of the light-emitting device. FIG. 4 shows an arrangement of the first portion (M1) relative to the second portion (M2) of the first embodiment of the light-emitting device. The first portion (M1) surrounds the second portion (M2). To be specific, as shown in FIG. 4, the first portion (M1) has a surrounding portion that surrounds the second portion (M2) and a plurality of fingers extending inwardly from the surrounding portion, so as to increase the current uniformity of the light-emitting device. The arrangement of the first portion (M1) and the second portion (M2) is not limited to that shown in FIG. 4, and may be designed according to actual chip sizes and shapes.

In the light-emitting device shown in FIG. 1, the first portion (M1) of the semiconductor laminate 120 includes a current conduction section 132 and a patterned structure 133 above the current conduction section 132. The patterned structure 133 has a densely arranged valley-plateau contour. Specifically, the patterned structure 133 has a first surface (S11) constituted by the first semiconductor layer 121, a second surface (S12) opposite to the first surface (S11) and away from the first semiconductor layer 121, and a side surface (S13) interconnecting the first surface (S11) and the second surface (S12). As shown in FIG. 1, the second surface (S12) is an upper surface and is elevated above the first surface (S11) that is a lower surface. The patterned structure 133 may be formed by removing a part of the second semiconductor layer 123, a part of the active layer 122, and optionally a part of the first semiconductor layer in the first portion (M1) and exposing the first semiconductor layer 121. In certain embodiments, the patterned structure 133 of the first portion (M1) includes a plurality of holes 1331 extending from the second surface (S12) to the first surface (S11), and exposing the first surface (S11).

A distance (D1) between the second surface (S12) and the first surface (S11), i.e., a height of the patterned structure 133, is controlled to be not less than half the thickness of the first semiconductor layer 121 so as to ensure that the charge carriers, when injected into the first portion (M1) in the light-emitting device, do not migrate directly toward the active layer 122 in the second portion (M2). Instead, the charge carriers move towards the first semiconductor layer 121 of the second portion (M2) through the current conduction section 132 of the first portion (M1). Subsequently, the charge carriers spread throughout the first semiconductor layer 121 beneath the active layer 122 in the second portion (M2), so that more charge carriers in the first (e.g., n-type) semiconductor layer 121 may participate in movement, and carrier injection efficiency may be improved. In certain embodiments, the distance (D1) may range from 60% to 95% of the thickness of the first semiconductor layer 121. In certain embodiments, the height of the patterned structure 133, i.e., the distance (D1), is not less than 500 nm, e.g., 0.6 μm or greater, so that the charge carriers injected form the second surface (S12) of the first portion (M1) may flow through the current conduction section 132 and into the first semiconductor layer 121 beneath the active layer 122 in the second portion (M2), and the charge carriers may further spread all over the first semiconductor layer 121 in the second portion (M2) and then uniformly flow into the active layer 122 in the second portion (M2). In certain embodiments, the distance (D1) may range from 0.5 μm to 3 μm, such as 600 nm, 1.2 μm, 1.8 μm, 2 μm, 2.5 μm or 3 μm.

The current conduction section 132 is located below the patterned structure 133, and is constituted by the first semiconductor layer 121 that is configured to transfer charge carriers injected from the first portion (M1) toward the second portion (M2). The current conduction section 132 has a thickness (D2) that may be altered according to a height of the isolation structure 131 in the thickness direction, thereby adjusting the efficiency of the charge carriers injected into the second portion (M2). The thickness (D2) is also a distance between the first surface (S11) and a lower surface (S201) of the first semiconductor layer 121 that is distal from the active layer 122. In certain embodiments, the thickness (D2) of the current conduction section 132 is between 0.2 to 0.5 times the thickness of the first semiconductor layer 121. If the thickness (D2) of the current conduction section 132 is too small, this may lead to a current crowding effect when the charge carriers arrive at the current conduction section 132, and cause a reduced injection of the charge carriers. If the thickness (D2) of the current conduction section 132 is too great, however, it may be detrimental to the spreading of the charge carriers. In some embodiments, the current conduction section 132 has a doping concentration of no less than 5×10¹⁸/cm³ and the thickness (D2) ranging from 0.2 μm to 1 μm, for example, from 0.3 μm to 0.6 μm. In certain embodiments, the first surface (S11) is no less than 200 nm away from the active layer (122). In the structure shown in FIG. 1, the isolation structure 131 has a bottom that is located at a level in the thickness direction between the first surface (S11) and a surface of the active layer 122 that is opposite to the second semiconductor layer 123 and adjacent to the first semiconductor layer 121. With this configuration, when the light-emitting device is powered, charge carriers may move from the first portion (M1) through the first semiconductor layer 121 beneath the isolation structure 131 and toward the first semiconductor layer 121 in the second portion (M2). Accordingly, the thickness (D2) of the current conduction section 132 may be appropriately reduced. That is to say, the patterned structure 133 may have the valley-plateau contour with deeper valleys, e.g., an increased depth of the holes 1331 for the embodiments shown in FIG. 1. In certain embodiments, the thickness (D2) ranges from 200 nm to 500 nm, for example, 300 nm. This configuration is advantageous for increasing the contact area of the first contact electrode 141 and the first semiconductor layer 121, and on the other hand, advantageous for journey of the charge carriers injected through the first portion (M1), including passing through the current conduction section 132 of the first portion (M1), and spreading across the first semiconductor layer in the second portion (M2), and moving uniformly into the active layer 122 of the second portion (M2). In some embodiments, the bottom of the isolation structure 131 and the first surface (S11) are substantially at the same level in the thickness direction. With this configuration, when the light-emitting device is powered, all of the carriers injected through the first portion (M1) may pass through the current conduction section 132 under the patterned structure 133 and move toward the second portion (M2). In certain embodiments, the thickness (D2) of the current conduction section 132 ranges from 400 nm to 900 nm, such as 600 nm or 800 nm.

In the light-emitting device mentioned above, the diameters of the holes and spacing between the holes 1331 are controlled such that the holes 1331 are densely arranged in the first portion (M1). Specifically, on the imaginary plane perpendicular to the thickness direction of the semiconductor laminate 120, the area ratio of the projection of the first surface (S11) exposed from the holes 1331 to the projection of the first portion (M1) may be not less than 0.3. The holes 1331 each have a diameter that ranges from 1 μm to 20 μm, and are spaced apart from one another by a distance that ranges from 2 μm to 15 μm. In one embodiment, the area ratio of the projection of the first surface (S11) exposed from the holes 1331 to the projection of the first portion (M1) may range from 0.5 to 0.8. The diameter of the hole 1331 may range from 1.5 μm to 4 μm, and the distance between two adjacent ones of the holes 1331 is 5 μm. Such a design enables good hole structures to be formed for the patterned structure and avails formation of the first contact electrode 141 penetrating into the holes.

The first contact electrode 141 is formed on the first portion (M1). More specifically, the first contact electrode 141 is formed on the second surface (S12), runs into the holes 1331 and reaches the first surface (S11), and is in contact with the first surface (S11) and sidewalls defining the holes 1331 so as to form ohmic contact with the first semiconductor layer 121. In certain embodiments, on the imaginary plane perpendicular to the thickness direction of the semiconductor laminate 120, the area ratio of a projection of the first contact electrode 141 to a projection of the first portion (M1) is not less than 0.4, e.g., between 0.4 and 0.9, so that the size of the contact area between the first contact electrode 141 and the first semiconductor layer 121 may be sufficient which improves the photoelectric performance of the light-emitting device. The second contact electrode 142 is formed on the second semiconductor layer 123 in the second portion (M2), and forms ohmic contact with the second semiconductor layer 123.

In one specific embodiment, the first contact electrode 141 is made of a material including one or more of Cr, Pt, Au, Ni, Ti, Al. Since the first semiconductor layer 121 generally includes at least a certain amount of Al, the first contact electrode 141, after being deposited on the first portion (M1), needs to undergo a high-temperature fusion process to form an alloy, for example, a Ti—Al—Au alloy, a Ti—Al—Ni—Au alloy, a Cr—Al—Ti—Au alloy, a Ti—Al—Au—Pt alloy, and the like, thereby forming good ohmic contact with the first semiconductor layer 121. In certain embodiments, the second contact electrode 142 may be made of an transparent conductive oxide material or a metal alloy such as NiAu, NiAg, NiRh, and the like. In certain embodiments, the second contact electrode 142 has a thickness that is 30 nm or less so as to minimize a light absorption rate for light emitted from the active layer 122. In certain embodiments in which the emitted light having a wavelength of 280 nm or less, the second contact electrode 142 is made of an indium tin oxide (ITO) and has a thickness ranging from 5 nm to 20 nm, such as from 10 nm to 15 nm. The light absorption rate of the ITO layer for the light emitted by the active layer may be reduced to 40% or less.

In the embodiment shown in FIG. 1, the isolation trench is disposed between the first portion (M1) and the second portion (M2) and serves as the isolation structure 131. The second surface (S12) of the patterned structure in the first portion (M1) is substantially flush with an upper surface (S203) of the second portion (M2). A plurality of holes 1331 are formed in the first portion (M1), and extend from the second surface (S12) toward the first semiconductor layer 121. The plurality of holes 1331 are densely arranged and extend deeply into the first semiconductor layer 121. In one embodiment, the thickness of the first semiconductor layer 121 may range from 1.5 μm to 3.5 μm. In certain embodiments, the distance (D1) is more than 1 μm and not greater than 3 μm, so that the charge carriers injected through the second surface (S12) may evenly spread and then flow through the current conduction section 132 and into the first semiconductor layer 121 in the second portion (M2), and eventually flow uniformly into the active layer 122 in the second portion (M2), thereby resulting in an enhanced photoelectric conversion efficiency of the light-emitting device.

Referring to FIG. 6, in some embodiments, the light-emitting device 100 is a flip chip light-emitting device. The light-emitting device 100 may further include a first connection electrode 151, a second connection electrode 152, an insulation layer 160, a first electrode pad 171, and a second electrode pad 172, as shown in FIG. 6. Furthermore, the first connection electrode 151 is formed on the first contact electrode 141, and the second connection electrode 152 is formed on the second contact electrode 142. In certain embodiments, each of the first and second connection electrodes 151, 152 has a multi-layered metallic structure that is formed, for example, by depositing, among others, an adhesion layer and a conductive layer in sequence on a corresponding one of the first and second contact electrodes 141, 142. In certain embodiments, the first connection electrode 151 completely covers the first contact electrode 141. Such an arrangement may, on one hand, increase the height of the first portion (M1) and, on the other hand, also provide protection for the first contact electrode 141.

The insulation layer 160 is formed on and covers the first and second connection electrodes 151, 152 and an outer sidewall of the semiconductor laminate 120. The insulation layer 160 also covers the first portion (M1) and the second portion (M2). The insulation layer 160, as shown in FIG. 6, has two openings respectively over the first portion (M1) and the second portion (M2) for exposing the first connection electrode 151 and the second connection electrode 152, respectively.

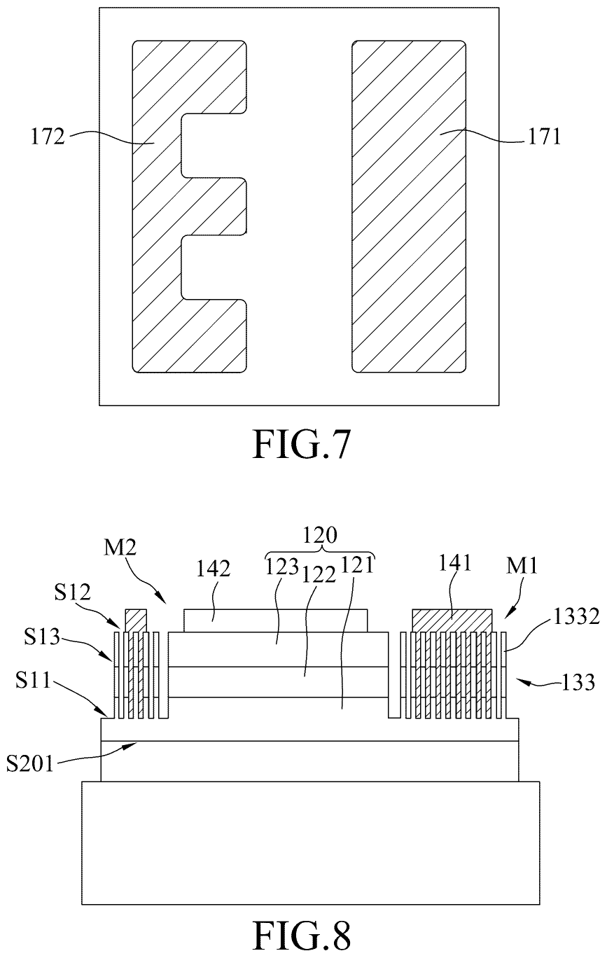

The first electrode pad 171 and the second electrode pad 172 are located on the insulation layer 160 and are electrically connected to the first connection electrode 151 and the second connection electrode 152 through the openings, respectively. The first electrode pad 171 and the second electrode pad 172 may be formed from the same material by the same process, and may be formed simultaneously by patterning a pad layer. The first and second electrode pads 171, 172 may be made of a material including one or more of Cr, Pt, Au, Ni, Ti, Al, and AuSn. In certain embodiments, the first electrode pad 171 is formed on and forms an electrical contact with the exposed first connection electrode 151, and the second electrode pad 172 is formed on and forms an electrical contact with the exposed second connection electrode 152. As mentioned above, the second surface (S12) of the first portion (M1) is flush with the upper surface of the second portion (M2), an electrode structure, e.g., the contact electrodes 141, 142, formed on such flush arrangement of surfaces may, therefore, withstand more pushing/pulling stress, leading to improved reliability of the light-emitting device. As shown in FIG. 7, in some embodiments, a projection of the first electrode pad 171 on the semiconductor laminate 120 is a rectangle in shape, and a projection of the second electrode pad 172 on the semiconductor laminate 120 has a shape including a body and several arms extending from the body toward the projection of the first electrode pad 171. Such configuration may prevent the second electrode pad 172 from overlapping or intersecting the first contact electrode 141 in the thickness direction, thereby advantageously improving the reliability of the light-emitting device.

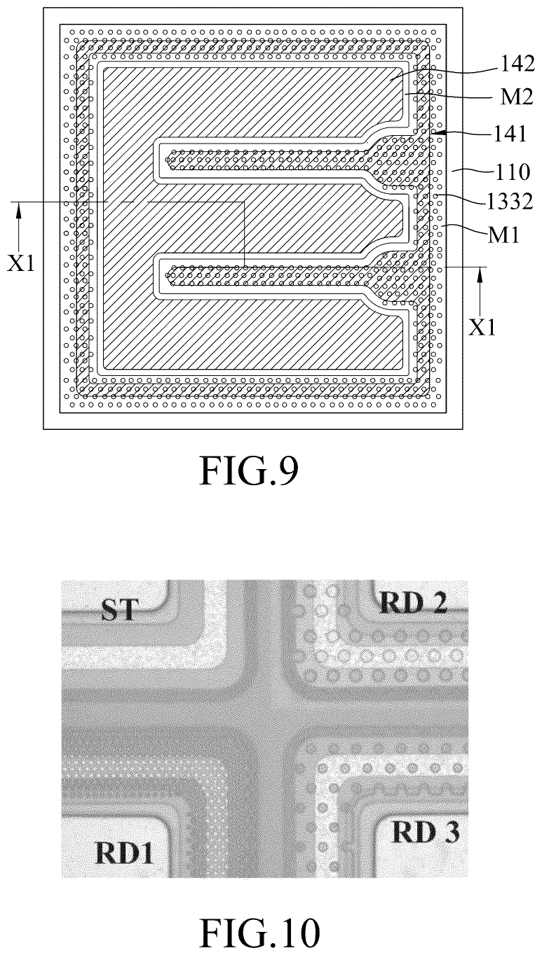

FIG. 8 and FIG. 9 are schematic views of a second embodiment of the light-emitting device according to the present disclosure. This embodiment generally includes the same elements and arrangement as those described in the first embodiment, except for the first portion (M1).

Referring to FIG. 9, the first portion (M1) of the second embodiment of the light-emitting device according to the present disclosure has a plurality of posts 1332 protruding from the first surface (S11) that is constituted by the first semiconductor layer 121, so as to form the patterned structure 133 with the valley-plateau contour. Top surfaces of the posts 1332 cooperatively constitute the second surface (S12) of the first portion (M1) so that, in this embodiment, the second surface (S12) is a discontinuous surface. In certain embodiments, the posts 1332 each have a diameter that ranges from 1 μm to 20 μm, such as 3 μm to 10 μm, and are spaced apart from one another by a distance that ranges from 2 μm to 15 μm. In this configuration, the posts 1332 may increase the contact area between the first contact electrode 141 and the first semiconductor layer 121, thereby improving the carrier injection efficiency. On the other hand, the posts 1332 may act as light-guiding posts for scattering the light reflected from the substrate 110, thereby improving the light extraction efficiency of the light-emitting device. Furthermore, on the imaginary plane perpendicular to the thickness direction of the semiconductor laminate 120, the area ratio of a projection of the first surface (S11) uncovered by the posts 1332 to a projection of the first portion (M1) is 0.5 or more, in certain embodiments, ranging from 0.5 to 0.85, to ensure a proper contact area between the first contact electrode 141 and the first surface (S11).

In this embodiment, the distance (D1) between the first surface (S11) and the second surface (S12) of the first portion (M1) , i.e., a height of the post 1332, is controlled to be not less than half the thickness of the first semiconductor layer 121. In certain embodiments, the distance (D1) may range from 60% to 95% of the thickness of the first semiconductor layer 121. In certain embodiments, the distance (D1) is not less than 500 nm, e.g., 0.6 μm or greater. In certain embodiments, the distance (D1) may range from 0.5 μm to 3 μm, e.g., may range from 1 μm to 2.5 μm, such as 600 nm, 1.2 μm, 1.8 μm, 2 μm or 2.5 μm. This ensures that the charge carriers, after being injected into the first portion (M1), flow through the current conduction section 132 and then into the first semiconductor layer 121 in the second portion (M2). In other words, the charge carriers spread throughout the first semiconductor layer 121 first and then uniformly flow into the active layer 122 in the second portion (M2). If the distance (D1) is too small, this may cause the charge carriers injected into the light-emitting device to directly migrate toward the active layer 122 in the second portion (M2), leading to a poor charge carrier injection efficiency. If the distance (D1) is too great, this may lead to a current crowding effect as the charge carriers injected from the first portion (M1) pass through the current conduction section 132, resulting in a reduced injection efficiency of the charge carriers.

In some embodiments, the first semiconductor layer 121 is doped with an n-type dopant, and may include a highly-doped sublayer and a lowly-doped sublayer. The lowly-doped sublayer is located between the active layer 122 and the highly-doped sublayer, so as to confine the charge carriers in the active layer 122. In certain embodiments, the highly-doped sublayer has a doping concentration at least 1.2 times a doping concentration of the lowly-doped sublayer. In certain embodiments, the doping concentration of the lowly-doped sublayer is less than 1×10¹⁸/cm³, such as between 2×10¹⁷/cm³ and 1×10¹⁸/cm³. In certain embodiments, the lowly-doped sublayer has a thickness ranging from 20 nm to 100 nm. In certain embodiments, the doping concentration of the highly-doped sublayer is generally ¹⁸/cm³ or more, such as 1×10¹⁹/cm³ or more, for example, between 1×10¹⁹/cm³ and 5×10¹⁹/cm³. The first surface (S11) of the first portion (M1) is constituted by the highly-doped sublayer, which facilitates the first contact electrode 141 to form good ohmic contact with the first semiconductor layer 121 at the first surface (S11). Furthermore, the first semiconductor layer 121 may further include a spreading layer that is disposed between the lowly-doped sublayer and the highly-doped sublayer and that has a doping concentration of 2×10¹⁸/cm³ or more, for example, between 5×10¹⁸/cm³ to 3×10¹⁹/cm³. Such a design may ensure good crystal quality of the first semiconductor layer 121 while enhancing the spreading of the charge carriers, so that the charge carriers injected from the first surface (S11) of the first portion (M1) may travel through the current conduction section 132 into the highly-doped sublayer of the first semiconductor layer 121 in the second portion (M2), and then laterally spread all over the spreading layer, and eventually uniformly flow into the active layer 122.

The light-emitting device according to the present disclosure may provide an improved charge carrier injection efficiency for the n-type AIGaN semiconductor layer, thereby improving the light-emitting efficiency. For comparing the light-emitting efficiencies, four types of samples, one for a conventional LED (i.e., Sample ST) and three for the light-emitting devices according to different embodiments of the present disclosure (i.e., Samples RD1, RD2, and RD3), were tested. The four types of samples were manufactured from one epitaxial multilayer structure (constituted by the first semiconductor layer 121, the active layer 122 and the second semiconductor layer 123) and constructed to have the same configurational distribution of the first portion (M1) and the second portion (M2) (referring to FIG. 4). The four types of the samples had same second portions (M2) while having different first portions (M1). FIG. 10 shows the configurations of the first portions (M1) of the four types of samples. Specifically, the first portion (M1) of Sample ST was a conventional platform portion that was constituted by the first semiconductor layer 121 and did not have the patterned structure 133 with the valley-plateau contour. Samples RD1 and RD2 had the first portion (M1) as shown in FIG. 1, while the holes 1331 of Sample RD1 each have a diameter of about 1.8 μm and are spaced apart from one another by a distance of about 2 μm, and the holes 1331 of Sample RD2 each have a diameter of about 5 μm and are spaced apart from one another by a distance of about 6 μm. Sample RD3 had the first portion (M1) as shown in FIG. 8, with the posts 1332 each having a diameter of about 5 μm and being spaced apart from one another by a distance of about 6 μm.

On the other hand, for each of the four types of samples, samples with different heights of the patterned structure were also manufactured to evaluate the light-emitting efficiencies. The height of the patterned structure referred here represents the distance (D1) between the first surface (S11) and the second surface (S12) of the first portion (M1) for the Samples RD1, RD2 and RD3, and a distance (DM) in the thickness direction between an exposed surface of the first semiconductor layer 121 of the first portion (M1) and an upper surface of the second semiconductor layer 123 of the second portion (M2).

TABLE 1

| Lot Nos. of the | Distance (D1) or | | |
|---|---|---|---|
| epitaxial multilayer | distance (D_{M}) | | |
| structure | (nm) | Sample | ΔLOP |
| 208002-04-C | 600 | ST | / |
| | | RD1 | 1.40% |
| | | RD2 | 0.58% |
| | | RD3 | 2.41% |
| 208002-09-C | 1200 | ST | / |
| | | RD1 | 3.51% |
| | | RD2 | 2.13% |
| | | RD3 | 3.87% |
| 208002-10-C | 1500 | ST | / |
| | | RD1 | 5.03% |
| | | RD2 | 2.67% |
| | | RD3 | 4.75% |

Table 1 shows the differences in light output power (LOP) of Samples RD1, RD2, and RD3 compared to Sample ST. It was noted that all of Samples RD1, RD2, and RD3 in all different depths had improved light-emitting efficiencies as compared to Sample ST. Furthermore, Sample RD1, as compared to Sample RD2, has more densely arranged holes 1331 in the first portion (M1) which provides improved light-emitting efficiency of the light-emitting device. Moreover, for each of Samples RD1, RD2 and RD3, the greater the height of the patterned structure in the first portion (M1), the higher the improvement in light output efficiency of the light-emitting device. In addition, Sample RD3 having the patterned structure 133 formed of the posts 1332 as shown in FIG. 8 appears to show a greater improvement in light-emitting efficiency as compared to Sample RD2 which has the patterned structure 133 formed of the holes 1331 as shown in FIG. 1.

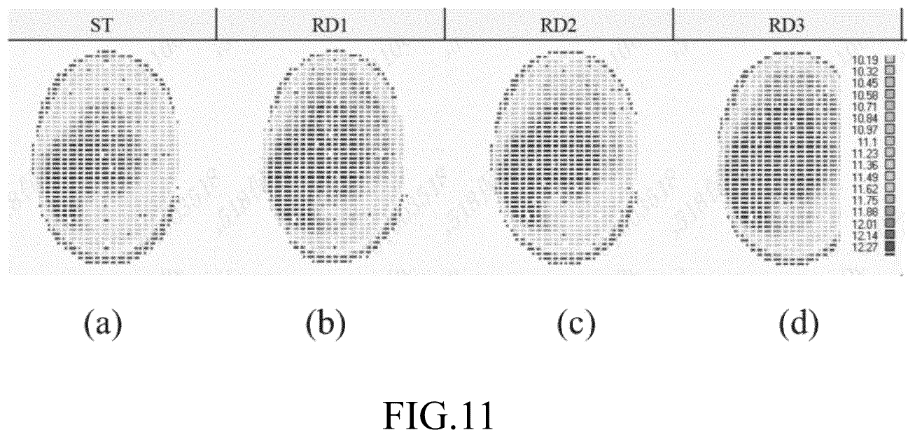

FIG. 11 shows the light output power mapping (LOP Mapping) for the light-emitting devices of the four samples manufactured from the epitaxial multilayer structure with Lot No. 208002-10-C. The level of shading represents intensity of light emitted from the light-emitting device, with darker shading indicating higher intensity of light. As shown in FIG. 11, Samples RD1, RD2 and RD3 exhibits improved light output power as compared to Sample ST, while Samples RD1 and RD3 exhibit more significant improvement.

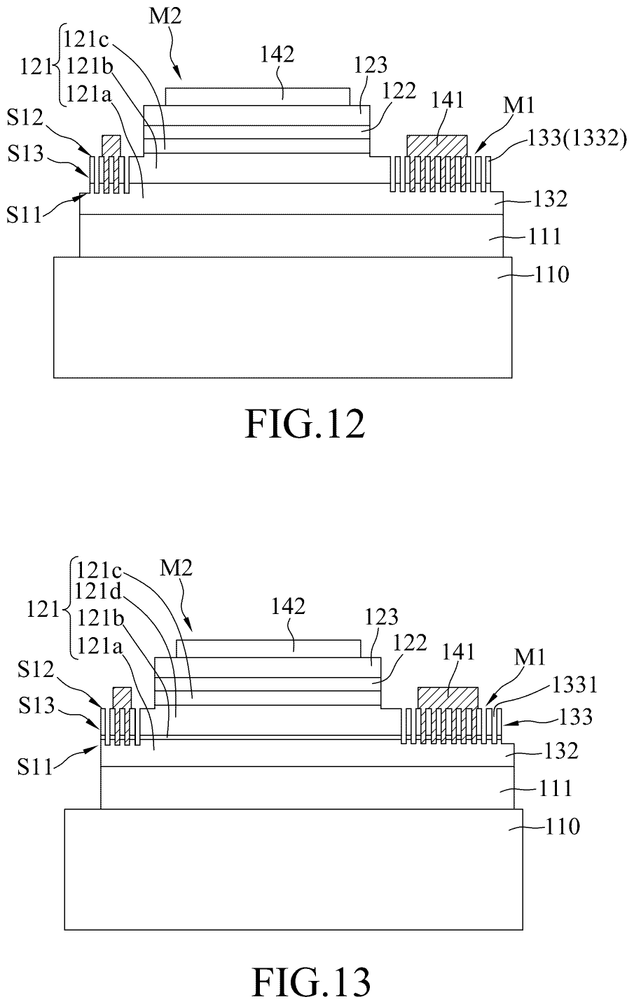

FIG. 12 is a schematic views illustrating a third embodiment of the light-emitting device according to the present disclosure, which has a similar structure to that of the second embodiment shown in FIG. 8, except for the height of the first portion (M1). The light-emitting device of the third embodiment has a top view that is similar to FIG. 9.

Referring to FIG. 12, the second surface (S12) of the first portion (M1) in the third embodiment is constituted by the first semiconductor layer 121. That is, the second surface (S12) of the first portion (M1) is lower than the upper surface (S203) of the second portion (M2). Specifically, in manufacturing the semiconductor laminate 120 of the light-emitting device in this embodiment, an epitaxial multilayer structure including the first semiconductor layer 121, the active layer 122 and the second semiconductor layer 123 is provided. The first semiconductor layer 121 includes a first sublayer 121a having a first doping concentration (C1), a second sublayer 121b having a second doping concentration (C2), and a third sublayer 121c having a third doping concentration (C3), and the three sublayers are arranged in the above described order from farther to closer with respect to the active layer 122, with C1>C2>C3. Then, a portion of the epitaxial multilayer structure is subjected to etching to remove the second semiconductor layer 123, the active layer 122, and optionally a portion of the first semiconductor layer 121 located in an area where the first portion (M1) is to be formed to expose a surface of the first semiconductor layer 121 (i.e., the second surface (S12) of the first portion (M1)) so as to obtain a preform of the first portion (M1). Then, the preform of the first portion (M1) is patterned to form a plurality of posts 1332 and expose the first surface (S11) so as to form the patterned structure 133 of the first portion (M1). In the embodiment shown in FIG. 12, the second surface (S12) of the first portion (M1) is lower than the surface of the active layer 122 that is opposite to the second semiconductor layer 123 and adjacent to the first semiconductor layer 121, that is, the first portion (M1) is below the active layer 122 in the thickness direction.

In one embodiment, the first semiconductor layer 121 is doped with an n-type dopant. The first semiconductor layer 121 in the second portion (M2) includes the first sublayer 121a, the second sublayer 121b, and the third sublayer 121c. In certain embodiments, the first doping concentration (C1) of the first sublayer 121a is at least 1.2 times the second doping concentration (C2) of the second sublayer 121b. The doping concentration (C1) of the first sublayer 121a is generally 5×10¹⁸/cm³ or more, such as 1×10¹⁹/cm³ or more, for example, between 1×10¹⁹/cm³ and 5×10¹⁹/cm³. The first semiconductor layer 121 in the first portion (M1) includes the first sublayer 121a and the second sublayer 121b. The first surface (S11) of the first portion (M1) is constituted by the first sublayer 121a, which facilitates the first contact electrode 141 to form good ohmic contact with the first semiconductor layer 121 at the first surface (S11). The doping concentration (C2) of the second sublayer 121b may be 2×10¹⁸/cm³ or more, for example, between 5×10¹⁸/cm³ and 3×10¹⁹/cm³. Such a design may ensure good crystal quality of the first semiconductor layer 121 while enhancing the spreading of the charge carriers, so that the charge carriers injected from the first surface (S11) of the first portion (M1) may travel through the current conduction section 132 and into the first sublayer 121a of the second portion (M2), and then spread all over the second sublayer 121 b, and eventually uniformly flow into the active layer 122. The third sublayer 121c is located between the second sublayer 121b and the active layer 122 to better confine the carriers in the active layer 122. In certain embodiments, the doping concentration (C3) of the third sublayer 121c is 1×10¹⁸/cm³ or less, for example, between 2×10¹⁷/cm³ and 1×10¹⁸/cm³, and the third sublayer 121c has a thickness that may range from 20 nm to 100 nm.

In this embodiment in which the second surface (S12) of the first portion (M1) is lower than the active layer 122, light loss due to absorption by the second semiconductor layer 123 and the active layer 122 in the first portion (M1) may be reduced. Furthermore, the posts 1332 of the pattern structure 133 may serve as light guide posts for scattering the light reflected from the substrate 110, thereby leading to an improved light extraction efficiency of the light-emitting device. On the other hand, ohmic contact between the first contact electrode 141 and the first portion (M1) (i.e., the first surface (S11) of the first portion) is formed in the highly-doped sublayer of the first semiconductor layer 121 that is far away from the active layer 122. Such a design may prevent the charge carriers injected 5 from the first portion (M1) from directly migrating to the active layer 122 of the second portion (M2). Instead, the charge carriers from the first portion (M1) may flow into the first sublayer 121a in the second portion (M2) through the current conduction section 132 of the first portion (M1) and subsequently sufficiently spread in the second sublayer 121b, which elicits movement and participation of 10 more charge carriers in the second sublayer 121b. That is, more charge carriers in the n-type AlGaN semiconductor layer can be utilized effectively and eventually flow uniformly into the active layer 122 in the second portion (M2), so that the carrier injection efficiency and the photoelectric conversion efficiency of the light-emitting device are improved.

FIG. 13 is a schematic views illustrating a fourth embodiment of the light-emitting device according to the present disclosure, which has the same structure as that of the third embodiment shown in FIG. 12, except for the structure of the first portion (M1). The light-emitting device of this embodiment has a top view that is similar to FIG. 2.

Referring to FIG. 13, the patterned structure 133 of the first portion (M1) of the light-emitting device according to this embodiment includes, instead of the posts 1332, a plurality of holes 1331 extending from the second surface (S12) into the first semiconductor 121 in the first portion (M1). Accordingly, the first contact electrode 141 contacts the second surface (S12) of the first portion, sidewalls defining the holes 1331, and the first surface (S11) exposed from the holes 1331.

In one embodiment, the first semiconductor layer 121 is doped with an n-type dopant. The first semiconductor layer 121 of the epitaxial multilayer structure includes a first sublayer 121a, a second sublayer 121b, a forth sublayer 121d, and a third sublayer 121c, arranged in the described order from farther to closer with respect to the active layer 122. The first sublayer 121a, the second sublayer 121b and the third sublayer 121c may be the same as those in the third embodiment. The fourth sublayer 121d is disposed between the second sublayer 121b and the third sublayer 121c, and may have a doping concentration higher than that of the second sublayer 121b. The doping concentration of the fourth sublayer 121d may be 5×10¹⁸/cm³ or more, such as 1×10¹⁹/cm³ or more, for example, between 1×10¹⁹/cm³ and 5×10¹⁹/cm³. The second surface (S12) of the first portion (M1) is constituted by the fourth sublayer 121d, which facilitates the first contact electrode 141 to form good ohmic contact with the first semiconductor layer 121 at the second surface (S12). The first surface (S11) exposed from the holes 1331 are constituted by the first sublayer 121a. The first sublayer 121a has a higher doping concentration that can facilitate the charge carriers to rapidly migrate toward the second portion (M2) via the current conduction section 132. The fourth sublayer 121d may have a sufficient thickness (e.g., 1 μm or more) for the spreading of the charge carriers. Moreover, having a lower doping concentration in the second sublayer 121b may facilitate maintaining both the crystal quality of the first semiconductor layer 121 and the spreading capability of the carriers.

In one variation of the fourth embodiment, the first portion (M1) of the light-emitting device is constituted by the first semiconductor layer 121 and a part of the active layer 122, that is, the second surface (S12) of the first portion (M1) is formed by the active layer 122. In this variation, the active layer 122 may be doped with an n-type dopant, such as Si, having a doping concentration that may be 1×10¹⁸/cm³ or more, such as between 1×10¹⁸/cm³ and 1×10¹⁹/cm³, for example, 2×10¹⁸/cm³, 5×10¹⁸/cm³, and the like. In this variation, properly doping the active layer 122 with an n-type dopant is advantageous for increasing the charge carrier concentration of the active layer 122, thereby improving the internal quantum efficiency. In this embodiment, at least a part of the first contact electrode 141 may directly contact the active layer 122.

In one embodiment, a bandgap of the active layer 122 is lower than that of the first semiconductor layer 121, which further facilitates the first contact electrode 141 to form good ohmic contact at the second surface (S12) of the first portion (M1).

In one embodiment, the semiconductor laminate 120 may include a confining layer (not shown) disposed between the active layer 122 and the second semiconductor layer 123. In certain embodiments, the confining layer contains a higher amount of Al and is lowly doped or not doped. A thickness of the confining layer may be 50 nm or less, which may prevent dopants in the second semiconductor layer 123 from spreading into the active layer 122, so as to improve the photoelectric performance of the light-emitting device.

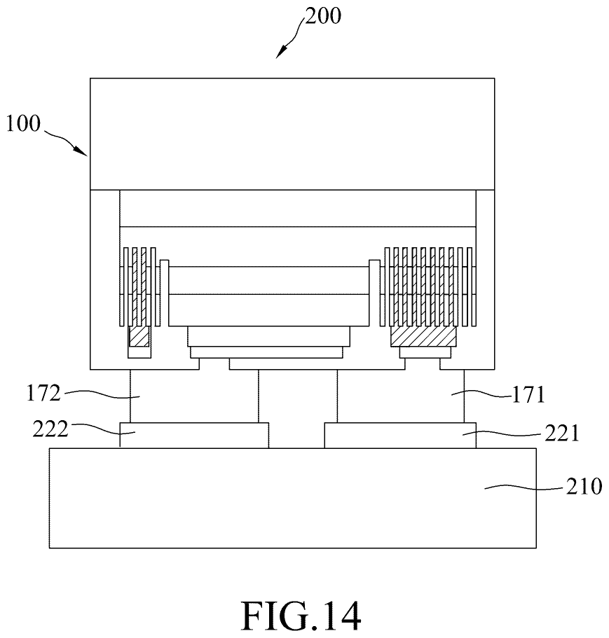

FIG. 14 schematically illustrates an embodiment of a light-emitting apparatus 200 according to the present disclosure that includes the light-emitting device 100 shown in FIG. 6. In this embodiment, the light-emitting device 100 is fixed on a circuit board 210 that is provided with a first conductive layer 221 and a second conductive layer 222 thereon. The first conductive layer 221 and the second conductive layer 222 are separated from each other. The first electrode pad 171 of the light-emitting device 100 is disposed on the first conductive layer 221 and is electrically connected to the first conductive layer 221. The second electrode pad 172 is disposed on the second conductive layer 222 and is electrically connected to the second conductive layer 222.

As described above, the distance (D1) between the second surface (S12) and the first surface (S11) in the first portion (M1) may be increased to improve the carrier injection efficiency of the first (e.g., n-type AlGaN) semiconductor layer 121, thereby improving the luminous efficiency of the light-emitting apparatus. Furthermore, by reducing the height difference between the first portion (M1) and the second portion (M2), the electrode pad can potentially withstand more pushing/pulling stress.

In this embodiment, since the first electrode pad 171 and the second electrode pad 172 have a similar size, the light-emitting apparatus has better electrode strength and reliability.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor laminate including a first semiconductor layer of a first conductivity, an active layer, and a second semiconductor layer of a second conductivity that is different from the first conductivity, said first semiconductor layer, said active layer and said second semiconductor layer being laminated in a thickness direction, said semiconductor laminate having
a first portion having a patterned structure that has a first surface constituted by said first semiconductor layer, a second surface opposite to said first surface and away from said first semiconductor layer, and a side surface interconnecting said first surface and said second surface, and
a second portion being a light-emitting area;
a first contact electrode formed on said first portion, electrically connected to said first semiconductor layer and being in contact with said first surface, said second surface and said side surface of said patterned structure; and
a second contact electrode formed on said second portion and electrically connected to said second semiconductor layer.

2. The light-emitting device according to claim 1, wherein said patterned structure of said first portion includes a plurality of posts protruding from said first surface, said posts having top surfaces that constitute said second surface.

3. The light-emitting device according to claim 1, wherein said patterned structure of said first portion includes a plurality of holes extending from said second surface to said first surface, said first surface being exposed from said holes, said first portion and said second portion being separated by an isolation structure.

4. The light-emitting device according to claim 1, wherein said first semiconductor layer has a lower surface that is distal from said active layer and is away from said first surface by a distance not less than 200 nm.

5. The light-emitting device according to claim 1, wherein said first semiconductor layer includes a first sublayer having a first doping concentration, and a second sublayer disposed between said first sublayer and said active layer and having a second doping concentration that is lower than said first doping concentration, said first surface being constituted by said first sublayer of said first semiconductor layer, said first contact electrode forming ohmic contact with said first sublayer at said first surface.

6. The light-emitting device according to claim 1, wherein said first semiconductor layer includes a first sublayer having a first doping concentration, and a third sublayer positioned between said first sublayer and said active layer and having a third doping concentration not greater than 1×10¹⁸/cm³, said first contact electrode forming ohmic contact with said first sublayer at said first surface.

7. The light-emitting device according to claim 1, wherein said first semiconductor layer includes a first sublayer having a first doping concentration, a second sublayer disposed between said first sublayer and said active layer and having a second doping concentration that is lower than said first doping concentration, and a third sublayer disposed between said second sublayer and said active layer and having a third doping concentration that is lower than said second doping concentration, said first electrode forming ohmic contact with said first sublayer.

8. The light-emitting device according to claim 7, wherein said first semiconductor layer further includes a fourth sublayer disposed between said second sublayer and said third sublayer and having a fourth doping concentration higher than said second doping concentration.

9. The light-emitting device according to claim 1, further comprising:
an insulation layer that is formed on said first contact electrode and said second contact electrode, and that covers said first portion and said second portion, said insulation layer having a first opening over said first portion and a second opening over said second portion;
a first electrode pad that is connected to said first contact electrode through said first opening of said insulation layer; and
a second electrode pad that is connected to said second contact electrode through said second opening of said insulation layer.

10. The light-emitting device according to claim 1, wherein said first portion surrounds said second portion.

11. The light-emitting device according to claim 1, wherein said patterned structure has a height that is not less than 500 nm.

12. The light-emitting device according to claim 1, wherein said first surface is no less than 200 nm away from said active layer.

13. The light-emitting device according to claim 1, wherein an area ratio of a projection of said first portion on an imaginary plane perpendicular to said thickness direction to a projection of said second portion on the imaginary plane is not less than 0.2.

14. The light-emitting device according to claim 1, wherein an area ratio of a projection of said first contact electrode on an imaginary plane perpendicular to said thickness direction to a projection of said first portion on the imaginary plane is not less than 0.4.

15. The light-emitting device according to claim 1, wherein an area ratio of said first surface to a projection of said first portion on an imaginary plane perpendicular to said thickness direction is not less than 0.3.

16. The light-emitting device according to claim 2, wherein said posts each have a diameter that ranges from 1 μm to 20 μm, and are spaced apart from one another by a distance that ranges from 2 μm to 15 μm.

17. The light-emitting device according to claim 3, wherein said holes each have a diameter that ranges from 1 μm to 20 μm, and are spaced apart from one another by a distance that ranges from 2 μm to 15 μm.

18. The light-emitting device according to claim 5, wherein said first semiconductor layer further includes a third sublayer disposed between said first sublayer and said active layer and having a third doping concentration lower than said second doping concentration.

19. The light-emitting device according to claim 18, wherein said third doping concentration of said third sublayer is not greater than 1×10¹⁸/cm³.

20. The light-emitting device according to claim 5, wherein said first doping concentration of said first sublayer is at least 1.2 times said second doping concentration of said second sublayer.
